(19) United States
(12) Patent Application Publication
(10) Pub. No.: US 2022/0165905 A1
(43) Pub. Date: May 26, 2022

(54) DEVICES AND METHODS INVOLVING DIAMOND-BASED PHOTOCONDUCTIVE STRUCTURES

(71) Applicant: The Board of Trustees of the Leland Stanford Junior University, Stanford, CA (US)

(72) Inventors: Srabanti Chowdhury, San Ramon, CA (US); Kelly Woo, Stanford, CA (US); Arunava Majumdar, Menlo Park, CA (US)

(21) Appl. No.: 17/531,561

(22) Filed: Nov. 19, 2021

Related U.S. Application Data
(60) Provisional application No. 63/116,529, filed on Nov. 20, 2020.

(51) Int. Cl. H01L 31/18; H01L 31/0288

(52) U.S. Cl. CPC H01L 31/1804; H01L 31/112; H01L 31/0288

(57) ABSTRACT

In certain examples, methods and photo-responsive structures are directed to devices involving a diamond-based photoconductive switch having a doped diamond-grown material in the switch. The doped diamond-grown material may be formed from different gases combined on a diamond seed, such that as grown, the diamond-based material manifests a controlled dopant concentration level of a polarity type and over a depth of optical absorption sufficient to ionize the dopants in response to an optical signal.

### BACKGROUND

Aspects of the present disclosure are related generally to the field of optical devices, and as may be exemplified by photoconductors.

High-power and/or high-temperature electronics provide an environment for many applications relating to and being benefited by aspects of the present disclosure. Consider, for example, high-power electronics applications such as where output power requirements are in excess of about 100 kW. Many semiconducting devices and materials used in such devices breakdown physically and/or functionally due to attributes specific to the types of devices and materials involved. For these reasons, ongoing research has pursued implementation of such devices and related materials which do not experience such issues.

Diamond is one material that has been the subject of such research. This follows as diamond has been considered an ideal material for high power and high temperature electronics because of certain material-specific properties of interest. Recent advances made in connection with the research involving the contributors/inventors of the present disclosure and involving using phosphorus for n-type doping have established the potential of vertical p-n-p and p-n-i-p power devices based on homoepitaxial diamond layers. In connection with certain efforts in this regard, such work has demonstrated p-i-n diodes blocking up to 1 kV.

However, such research has also confirmed some of the difficulties recognized in attempts to implement a semiconductor device based on or using a doped diamond layer in high-power electronics including for example, those involving n-type doping of a diamond layer as in p-n junction-based devices, and optically triggered switches and/or photoconductive switches.

### SUMMARY OF VARIOUS ASPECTS AND EXAMPLES

Various aspects and examples according to the present disclosure (including the Appendix of the underlying U.S. provisional application) are directed to issues such as those addressed above and/or others which may become apparent from the following disclosure. Using exemplary contexts, for example involving electronic-based structures such as photoconductive switch (PCSS), Gate Turn Off Thyristor (GTO), Silicon Controlled Rectifier (SCR), high-voltage metal-oxide-semiconductor field-effect transistors (MOSFETs) among others, certain advancements according to specific examples of the present disclosure utilize doped diamond substrates to excite carriers by sub-bandgap photon energies while maintaining the desirable properties of diamond that would facilitate higher breakdown field and better thermal management.

According to certain specific aspects, the present disclosure is directed to methods, photo-responsive apparatuses and devices involving a diamond-based photoconductive switch having a doped diamond-grown material in the switch. The doped diamond-grown material may be formed from different gases combined on a diamond seed, such that as grown, the diamond-based material manifests a controlled dopant concentration level of dopants of a polarity type and over a depth of optical absorption sufficient to ionize the dopants in response to an optical signal (and may also exhibit broadening of donor level). Building on this effect due to the ionization, in a more-specific related aspects on/off state current ratios of such a photo-responsive apparatus a device may be enhanced (e.g., increased or preferably optimized) for high performance switching such that in the device's off state, the material conductance (as a function of the ionized dopants) decreases with lower doping levels or compensation, whereas in the on state, the conduction is increased due to the photogeneration of free carriers through dopants and traps, thereby increasing doping concentration subject to certain aspects of the design (e.g., excitable carriers based on the surface area of the substrate and absorption depth at the excitation wavelength of the optical signal). Such manifestation sufficient to ionize the dopants then reduces the resistance in the contacts, in conjunction with free flow of ions across a channel in the material, so as to realize the desired performance in response to the optical signal.

In more specific embodiments, the above type of photo-responsive apparatuses (and/or structures) may include: a plurality of contacts, with each being respectively coupled to the diamond-based photoconductive switch; and an excimer source to generate the optical signal at energies greater than an activation energy and less than the bandgap of the doped diamond-grown material, wherein the diamond-based photoconductive switch is to respond to the generated energies by generating electric current via at least one of the plurality of contacts.

In one specific type of embodiment, the above type of photo-responsive apparatus is a system (or a device) which includes and/or is responsive to an excimer source. The optical absorption is to occur in response to the excimer source, and this occurs in conjunction with free carriers generated in the doped diamond-grown material to be sourced primarily from atoms of one or more dopants of the doped diamond-grown material.

In certain related, specific examples and contexts including, but not limited to, the above-discussed examples and contexts, aspects of the present disclosure include and/or are directed to one or a combination of two or more of the following: a diamond-based photoconductive switch having an n-type material including one or more dopants with a doping level (roughly) in the range from 10¹⁹ cm⁻³ to 10²⁰ cm⁻³; an n-type material or layer formed by combining gases on a diamond seed and manifesting a controlled concentration of one or more n-type dopants via a depth profile; and a diamond-grown layer or a device including a diamond-grown layer.

In a more specific embodiment, an n-type material or layer is formed by combining gases on a diamond seed and manifesting a controlled concentration of one or more n-type dopants via a depth profile. For specific experimental examples involving an n-type dopant, the dopant may be phosphorous (or nitrogen) and hydrogen plasma may be used as a gas during a growth process for the diamond layer, with methane (CH4) as the source of carbon, and/or trimethyl phosphine (TMP) diluted with hydrogen (P(CH3)3) as the source of phosphorus. Similarly, where a p-type dopant is used during the growth process for the diamond layer, boron may be used. It is appreciated, however, that such specifics are for the purposes of discussing examples and other dopants may be found useful (e.g., for n-type, also arsenic and Group-IV elements).

Yet other related aspects of the present disclosure, also optionally building on one or more of the above examples, include and/or are directed to a method of manufacturing a diamond-grown layer or a device including a diamond-grown layer. The method may comprise one or a combination of two of more of the following: (a) combining gases and/or controlling the concentration of one or more n-type dopants on a diamond seed (e.g., via a vapor deposition tool such as a MPCVD and/or a vapor input control device); (b) removing any hydrogen conduction from the surface of the diamond-grown layer; (c) measuring or characterizing a depth profile of one or more n-type dopants in the diamond-grown layer (e.g., using secondary ion mass spectroscopy (SIMS)); and (d) measuring or characterizing the activation energy of the one or more n-type dopants in the diamond-grown layer.

The above discussion is not intended to describe each aspect, embodiment or every implementation of the present disclosure. The figures and detailed description that follow also exemplify various embodiments.

### BRIEF DESCRIPTION OF FIGURES

Various example embodiments, including experimental examples, may be more completely understood in consideration of the following detailed description in connection with the accompanying drawings, each in accordance with the present disclosure, in which:

FIGS. 1A and 1B respectively illustrate an example schematic viewgraph and an image of ignited plasma on a diamond seed, in accordance with one aspect of the present disclosure;

FIG. 2 illustrates a SIMS profile for an example embodiment of the present disclosure involving an n-type dopant material as a layer on certain oriented diamond;

FIG. 3 is an example schematic representation showing illumination of a material, formed in accordance with the present disclosure, and showing excited electrons slowing from dopant energy states to the conduction band to increase conductivity of the material;

FIGS. 4A and 4B illustrate schematics of basic planar and vertical photoconductive switches showing the general geometry of the contacts on the semiconductor material with the optical excitation source;

FIG. 4C illustrates the energy band diagram of diamond. This includes its bandgap and the activation energy of its dopants, boron, phosphorous, and nitrogen;

FIG. 4D illustrates the material properties of diamond in comparison to Si and other wide band gap materials GaN and SiC in accordance with certain example aspects of the present disclosure and useful in understanding examples of an apparatus and/or method according to the present disclosure;

FIG. 5 illustrates an example set of fabricated planar interdigitated photoconductive switches on nitrogen doped diamond with example electrical test structures;

FIG. 6 illustrates the optical setup used to generate a pulsed excitation for testing a photoconductive switch such as one of the structures depicted in FIG. 5;

FIG. 7 illustrates the measurement circuit used to record a photoresponse of an example photoconductive switch in conjunction with the example optical setup in FIG. 6;

FIG. 8 illustrates the photoresponse of a boron doped diamond sample with two contacts to a 532 nm laser pulse measured using the example circuit in FIG. 7;

FIG. 9 illustrates the peak voltage response across the load resistor of the circuit as a function of bias voltage across the electrodes;

FIG. 10 illustrates the photoresponse of a nitrogen doped diamond photoconductive switch pictured in FIG. 5 to a 532 nm pulsed laser; and

FIG. 11 is a graph showing plots, associated with yet another experimental example, of peak photocurrent of nitrogen-doped and implanted-boron devices up to 100V bias voltage.

While various embodiments discussed herein are amenable to modifications and alternative forms, aspects thereof have been shown by way of example in the drawings and will be described in detail. It should be understood, however, that the intention is not to limit the disclosure to the particular embodiments described. On the contrary, the intention is to cover all modifications, equivalents, and alternatives falling within the scope of the disclosure including aspects defined in the claims. In addition, the term “example” as used throughout this application is only by way of illustration, and not limitation.

### DETAILED DESCRIPTION

Aspects of the present disclosure are believed to be applicable to a variety of different types of apparatuses, systems and methods directed to or involving a doped diamond material layer as may be used in a high-powered electronics device or system. While the following discussion refers to certain n-type doping of diamond for certain apparatuses, such discussion is for providing merely an exemplary context to help explain such aspects, and the present disclosure is not necessarily so limited. The examples and specific applications discussed herein, in connection with the figures, and in the underlying U.S. provisional application and Appendix, may be implemented in connection with one or more aspects, examples (or example embodiments) and/or implementations, whether such aspects are considered alone or in combination with one another.

Accordingly, in the following description various specific details are set forth to describe specific examples presented herein. It should be apparent to one skilled in the art, however, that one or more other examples and/or variations of these examples may be practiced without all the specific details given below. In other instances, well known features have not been described in detail so as not to obscure the description of the examples herein. For ease of illustration, the same connotation and/or reference numerals may be used in different diagrams to refer to the same elements or additional instances of the same element. Also, although aspects and features may in some cases be described in individual figures, it will be appreciated that features from one figure or embodiment can be combined with features of another figure or embodiment even though the combination is not explicitly shown or explicitly described as a combination.

Exemplary aspects of the present disclosure are related to methods and devices involving a diamond-based photoconductive switch having a doped diamond-grown material in the switch. The doped diamond-grown material may be formed from different gases combined on a diamond seed, such that as grown, the diamond-based material manifests a controlled dopant concentration level of dopants of a polarity type and over a depth of optical absorption sufficient to ionize the dopants in response to an optical signal. Further, in response to the appropriate optical signals (e.g., wavelengths for such doped materials), on/off current ratios may be enhanced or maximized for high performance switching. This follows as in the optical switch's off state, the material conductance primarily depends on the number of ionized dopants, which decreases with lower doping levels or compensation, whereas in the on state, the conduction is increased due to the photogeneration of free carriers through dopants and traps, which increases with doping concentration. However, on-state conductance is also limited by the number of excitable carriers based on the surface area of the substrate and absorption depth at the excitation wavelength of the optical signal. Therefore, according to the present disclosure, with the conduction as a function of doping concentration between the on and off state, a doping level or range is chosen to set (e.g., maximize) the on/off current ratio in devices fabricated in such that the doped diamond-grown material manifests a controlled dopant concentration level with dopants of a polarity type and over a depth of optical absorption sufficient to ionize the dopants in response to an optical signal. For example, with this manifestation and dopant ionization, the resistance in the contacts is sufficiently reduced, in conjunction with free flow of ions across a channel in the material, so as to realize the desired performance of the optical switch.

Consistent with the above aspects, aspects of the present disclosure are directed to such devices and/or methods (e.g., involving manufacture, use, assembly and/or testing of such devices) as may be gleaned from the discussion of the present patent document and its underlying U.S. Provisional Application Ser. No. 63/116,529 filed on Nov. 20, 2020 (STFD.426P1), to which priority is claimed. To the extent permitted, such subject matter is incorporated by reference in its entirety generally and to the extent that further aspects and examples (such as experimental and/more-detailed embodiments) may be useful to supplement and/or clarify.

Consistent with the present disclosure, such devices and/or methods may be used for producing any of various types of photo-responsive devices and/or components, among others, and examples of such devices and components include: photoconductive switches (PCSS), gate turn off thyristors (GTO), silicon controlled rectifiers (SCR), high-voltage MOSFETs, etc.

According to certain aspects of the present disclosure, specific example embodiments may involve those mentioned above and may include and/or use excimer sources chosen with energies greater than the activation energy of dopants in a doped diamond-based material and less than the bandgap, and the free carriers generated will primarily be sourced from the dopant atoms rather than the carbon atoms from the diamond lattice. Boron is an example of a p-type dopant occupying substitutional sites, as boron has an activation energy which is greater than 0.25 eV (more specifically boron is at 0.37 eV) above the valence band. As n-type, nitrogen and/or phosphorous are examples which may be used together or alone as dopants in forming a doped diamond-based material as a relatively deep donor and a relatively shallow donor (e.g., with nitrogen being a deeper donor with an activation energy between 1.5 eV and 1.8 eV and phosphorous being a shallower donor with an activation energy between 0.4 eV and 0.7 eV below the conduction band).

Building on the above-characterized aspects, more specific examples involving multiple (e.g., commonly-sought) light wavelengths may be used to trigger a diamond-based photoconductive switch according to the present disclosure. Consider, as examples, for a band to band excitation an excimer source with wavelengths of ≤255 nm, and for boron, nitrogen, and phosphorous, wavelengths of ≤3.35 μm, 730 nm, and 2.06 μm, may be used respectively. According to these specific examples, a wide range of photon sources may be utilized (e.g., from ultraviolet to infrared) for triggering a doped diamond photoconductive switch such as a PCSS depending on the species of dopant. One application may include fabricating devices that operate with 1.55 um light, sometimes used in standard optical communication.

Again, in such PCSS-specific exemplary contexts for example in designing extrinsic PCSS, on/off current ratios should be maximized for high performance switching. In the off state, the material conductance primarily depends on the number of ionized dopants, which decreases with lower doping levels or compensation. In the on state, the conduction is increased due to the photogeneration of free carriers through dopants and traps, which increases with doping concentration. However, on-state conductance is also limited by the number of excitable carriers based on the surface area of the substrate and absorption depth at the excitation wavelength. Also in certain example methods according to the present disclosure, by analyzing the conduction as a function of doping concentration between the on and off state, a doping level or range (e.g., at 1e18 or in a range within 10% on either side of 1e18) may be chosen to maximize the on/off current ratio in fabricated devices. Accordingly, the doped diamond-grown material manifests a controlled dopant concentration level with dopants of a polarity type and over a depth of optical absorption sufficient to ionize the dopants in response to an optical signal. For example, with such ionization of the dopants, the resistance in the contacts can be sufficiently reduced, in conjunction with free flow of ions across a channel in the material, so as to realize the desired performance of the optical switch.

Other related aspects of the present disclosure, optionally building on one or more of the above examples, include and/or are directed to a system involving providing a diamond-grown layer, the system comprising one or more of the following: a device such as a vapor deposition tool (e.g., a MPCVD and/or a vapor input control device) to combine gases and/or to control the concentration of one or more dopants on a diamond seed; a mechanism (e.g., a vacuum or chemical reagent) to remove any hydrogen conduction from the surface of the diamond-grown layer; a mechanism such as a SIMS to measure or characterize a depth profile of the one or more dopants in the diamond-grown layer; and related test equipment to measure or characterize the activation energy of the one or more n-type dopants in the diamond-grown layer. In more specific example embodiments, the one or more dopants may of be the n-type or the p-type.

According to certain more specific examples, the present disclosure is directed to a method and alternatively, a device manufactured from the method involving a semiconductive structure or device having attributes recognizable from the manufacture. Such a device may be manufactured by forming a doped diamond-grown material by combining different gases on a diamond seed to manifest a controlled dopant concentration level of a polarity type and over a sufficient depth of optical absorption. As examples, this degree of sufficiency is recognized by the doped material ionizing the dopants in response to an optical signal of an appropriate wavelength for the dopants. The doped diamond-grown material is then secured to, for example, becoming part of, a diamond-based photoconductive switch. In certain more specific embodiments, such methodology may include using hydrogen plasma as one of the different gases during growth from the diamond seed, and using methane (CH4) as another of the different gases as a source of carbon. In other related specific embodiments, at least one dopants of the doped diamond-grown material includes phosphorus, and the method may further include using trimethyl phosphine (TMP) diluted with hydrogen (P(CH3)3) as a source of the phosphorus.

Also relating to the above methodology, and in yet further specific embodiments, the combining of the different gases may include using a vapor-input or vapor-deposition tool to combine the different gases and/or to control the dopant concentration level. Also and as noted above, the methodology may further include: removing hydrogen conduction from a surface of the diamond-grown material; measuring or characterizing a depth profile of one or more dopants of the polarity type in the doped diamond-grown material; and measuring or characterizing a level of activation energy of the one or more dopants in the diamond-grown layer.

The above methodology may involve testing and/or related use of the doped material, and this may involve use of an excimer source to cause the optical absorption and to excite carriers in the doped diamond-grown material by sub-bandgap photon energies. In this context, the above-mentioned forming step may include generating the doped diamond-grown material with thermal-management properties and voltage-breakdown properties that correspond to thermal-management properties and voltage-breakdown properties of diamond. In this regard, the resultant photoconductive switch and/or the doped diamond-grow material is advantaged directly by the above-discussed processing surrounding the diamond.

In connection with specific examples, such methodology is used with the optical absorption occurring in response to an optical signal provided by an excimer source (e.g., a laser generating light at one or more wavelengths), in conjunction with free carriers generated in the doped diamond-grown material to be sourced primarily from atoms of one or more dopants of the doped diamond-grown material. In these specific examples, the diamond-based photoconductive switch includes a p-n junction that converts photons into current and that manifests a breakdown voltage, in one instance, of at least 1 kV with a blocking electric field of at least 2 MV/cm. In other instances, the breakdown voltage is manifested at 2 kV, 5 kV and above 10 kV, respectively.

Various experimental example embodiments and aspects, some of which are discussed hereinbelow in connection with the above-noted, briefly-described figures, have demonstrated that the above-characterized aspects, structures and methodologies may be used in one or more devices to form certain semiconductor and/or optical-switch devices and circuits. Before discussing such examples in detail, however, it is noted that each of these examples is presented to illustrate exemplary aspects of the present disclosure largely as developed to validate proof of concept, and as might be recognized in the related discussion.

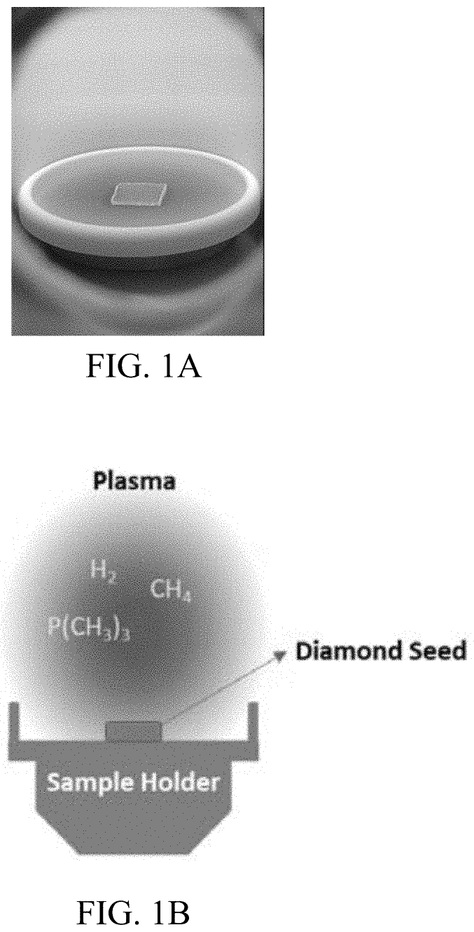

In example embodiments according to the present disclosure and as illustrated in connection with FIGS. 1A and 1B, a well-controlled phosphorus doped diamond growth on single-crystalline diamond seed is established in each of these depictions. FIG. 1A is a schematic viewgraph showing a perspective-like view, and FIG. 1B is an actual image from the side, of ignited plasma on a similarly-situated sample.

In certain specific examples consistent with a more-general embodiment shown in FIG. 1A and a more specific embodiment shown in FIG. 1B, this growth may be done on (100) and (111) surface orientations. A microwave plasma chemical vapor deposition (MPCVD) system, commercially available from SNSF, may be used. While various sources may be used (e.g., as depicted by the more-general embodiment of FIG. 1A), in connection with the more specific embodiment of FIG. 1B, hydrogen plasma is the main gas, methane (CH4) is the source of carbon, and trimethyl phosphine (TMP) diluted with hydrogen (P(CH3)3) is the source of phosphorus. In such experiments involving this more specific embodiment, values used for these input gases may be: hydrogen from 400 to 500 sccm; CH4 from 1 to 5 sccm; and TMP from 5 to 30 sccm. By changing the flow rate of TMP, the concentration of the phosphorus in the diamond grown layer is well controlled.

After the growth, the sample is oxygen-terminated to remove any hydrogen conduction from the surface. This can be done by a high temperature (H2SO4+HNO3 @˜200° C.) acid cleaning procedure. Next, the sample may be characterized using secondary ion mass spectroscopy (SIMS) to measure the depth profile of the dopants. Then, to measure the activation energy of the dopants, the resistivity and Hall effect is measured using van der Pauw configuration under ˜1 T magnetic field at different temperatures. This activation-energy measurement may be done from 4 K to 1273 K. By plotting ln(nT^{-3/2}) versus 1/T, where n is the carrier density (cm⁻³) and T is the temperature (K), the activation energy (ED) can be estimated from the slope of the fitted linear curve.

In order to measure the current output of a high-power photoconductive switch under illumination, a test circuit will be used. This circuit includes biasing part (capacitors and resistors), a high power 1.55 μm (for Phosphorus-doped diamond) or 0.8 μm (for Nitrogen-doped diamond) Nd:YAG laser in pulsed mode for illumination, and measurement part. In the measurement circuit, the output current passes through a Rogowski coil, then a 40-dB coaxial attenuator, and at the end will be measured by an oscilloscope. As may be expected, the pulsed mode for illumination appears as a digital (aka square-cornered) pulse having off-on-off attributes, whereas the measurement via such impedance circuitry retrieves an analog-signal response which generally follows the pulsed input but with gradual rise and fall slopes to characterize the pulse.

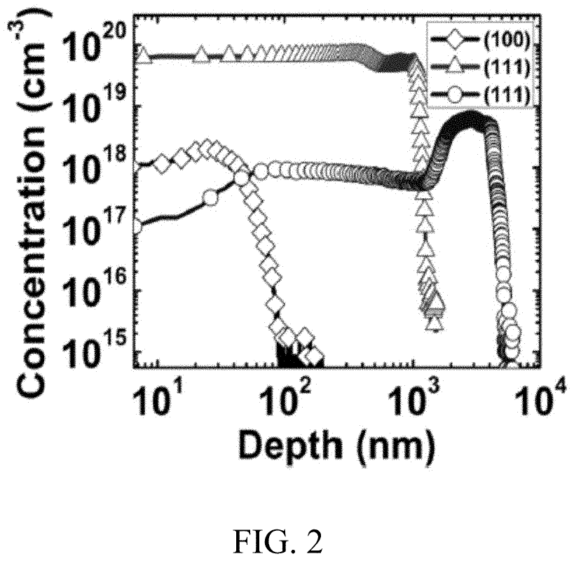

FIG. 2 illustrates a spectral ion mass spectroscopy (SIMS) profile, for an example embodiment of the present disclosure, involving an n-type dopant material as a layer on certain oriented diamond. As known from previous studies, at low doping concentrations, the number of ionized carriers is very low due to the deep level donors of phosphorus (˜0.6 eV below conduction band minima), at room temperature the level of ionization may be just 10⁻⁵˜10⁻⁶, and a high concentration of ˜10²⁰ cm⁻³ may be used or needed to reduce the activation energy by hopping conduction to 0.05 eV, and above the concentration of 2×10¹⁹ cm⁻³, effects may take place such as the donor level broadening and the donor concentration ND being lower than SIMS. In support, at high concentrations phosphorus is present in different chemical sites as may be observed by photoemission spectroscopy. As dopants get deeper in semiconductors (e.g., in wide bandgap), the dopant wave-functions start overlapping at much higher concentrations than in silicon.

According to the present disclosure and certain detailed experimental examples consistent with the above-mentioned embodiments, it has been discovered that n-type diamond with dopants at doping concentration levels of between 10¹⁹ and 10²⁰ cm⁻³, in response to an optical signal appropriate for the dopants, the doped material exhibits ionization of the dopants. By controlling phosphorous doping in diamond, photoconductivity studies in the material at around 1550 nm confirm that such doped diamond-grown material (being formed from different gases combined on a diamond seed) manifests a controlled dopant concentration level of a negative polarity type, over a depth of optical absorption sufficient, to exhibit ionization of the dopants in response to the appropriate optical signal.

Similarly, by controlling nitrogen doping in diamond, photoconductivity studies in the material at around 800 nm confirm that such doped diamond-grown material (also being formed from different gases combined on a diamond seed) manifests a controlled dopant concentration level of a positive polarity type over a sufficient depth of optical absorption in response to an optical signal; for example, the depth is to be sufficient to ionize the dopants.

More specifically, the SIMS profile of FIG. 2 corresponds to a P-doped n-type layer on (111)-oriented and (100)-oriented diamond. P-incorporation is readily achieved along the (111)-oriented direction and can be controlled as depicted above. P-incorporation along the (100)-oriented direction is achieved by plasma focusing using a protruding geometry on the sample holder which is water cooled and the usage of the pulsed deposition technique where the microwave power is switched off periodically keeping the dopant gas flowing.

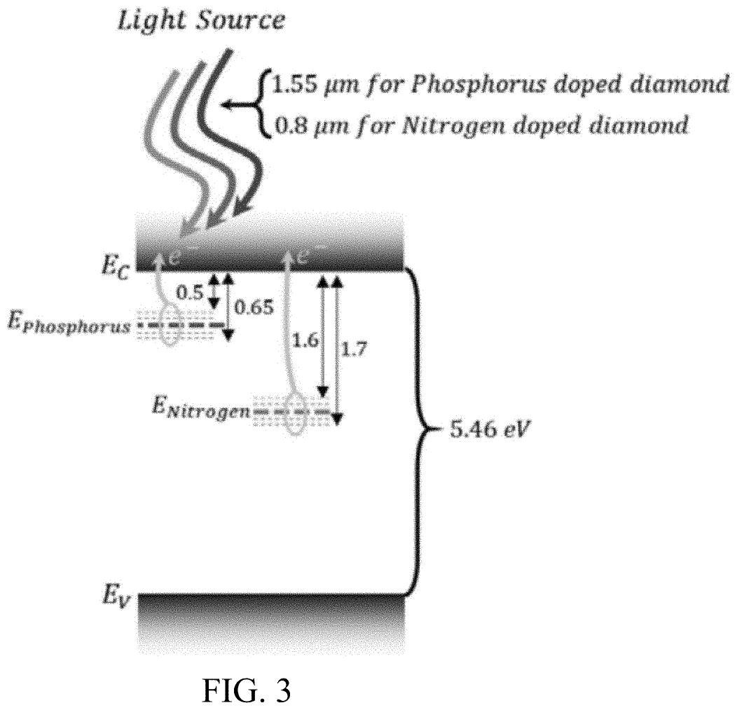

FIG. 3 is an example schematic representation showing illumination of a material, formed in accordance with the present disclosure, and showing excited electrons slowing from dopant energy states to the conduction band to increase conductivity of the material. More specifically and consistent with the above discussion, FIG. 3 shows that by illuminating the substrate using a Nd:YAG laser, electrons from dopants energy states will be excited to the conduction band, thereby increasing the conductivity of the material.

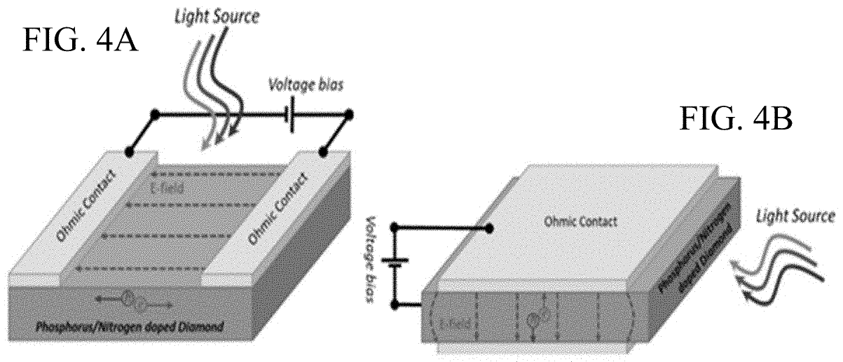

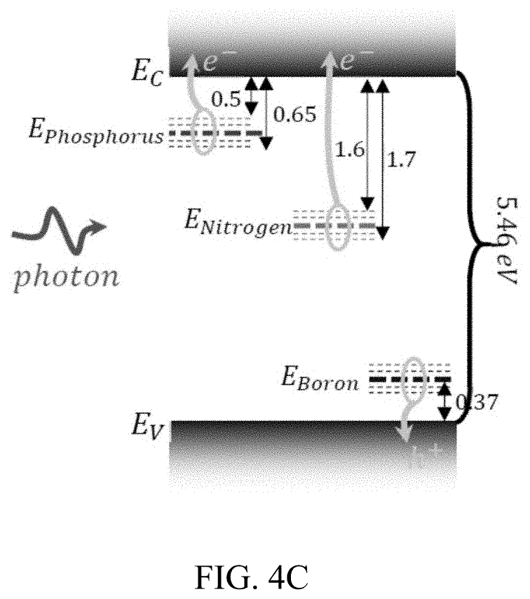

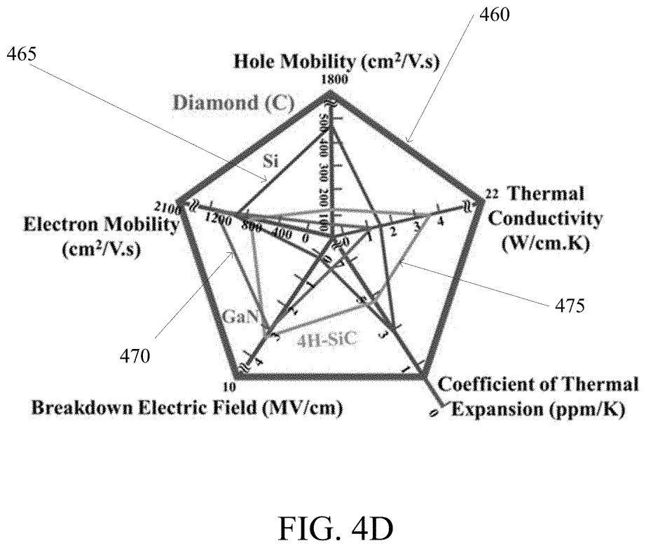

FIGS. 4A and 4B illustrate schematics of basic planar and vertical photoconductive switches, respectively, showing general geometries of contacts on semiconductor materials with the optical excitation source, and wherein each of the materials refer to or include a doped diamond-grown material. These and other contact-based orientations of photoconductive switches include, among other photoconductive switch types: PCSS, GTO (Gate Turn Off Thyristor), SCR (Silicon Controlled Rectifier), and high-voltage MOSFETs among others. According to certain examples of the present disclosure and using such exemplary contexts, advancements according to the present disclosure utilize doped diamond substrates to excite carriers by sub-bandgap photon energies while maintaining one or more desirable properties of diamond for purposes such as to facilitate higher breakdown field and/or better thermal management.

As a specific exemplary context, a photoconductive switch (PCSS) typically includes a semiconductive material, such as Si, GaAs, or SiC, etc., with two metal electrodes or contacts (which can be transparent or nontransparent) from which the device is connected to an electrical circuit. The switch is optically controlled by modulating the conductivity of the substrate semiconductor with a photon source such as a laser. When the energy from the photons is high enough to generate free carriers, the conductivity is increased by several orders of magnitude, thus allowing increased current. When there is no illumination, the number of free charges is significantly diminished, and the conductivity decreases to prevent the flow of current. Photoconductive switches are fabricated in lateral geometries, in which both electrodes are in contact with the substrate on the same plane, and in vertical geometries, in which contacts are on the opposite sides of the substrate.

This type of switching device can be applied to pulsed power technology for high speed and jitter free switching. These may include radar, particle acceleration, and pulsed high-power lasers. Furthermore, as there are increased efforts towards electrification to lessen our dependence on fossil fuel use, developing safe mechanisms for making and breaking high power circuits is a priority. By decoupling the trigger from the circuit, the chance of false triggering is lessened. However, a problem with such photoconductive switches is their short lifespan resulting from voltage and current overloads, as well as thermal runaway effects at high-power levels. Accordingly to one example consistent with the present disclosure, some of these issues may be mitigated by choosing to use a wide band gap material as the switch substrate, particularly diamond especially in light of diamond's material properties of interest which make it even more attractive than other wide band gap materials, such as SiC and GaN, for forming a photoconductive switch. Such properties of interest are as described above.

Due to the large bandgap of diamond, the off-state current of a PCSS device, or leakage current, will be low. In the on-state, low losses will be incurred and high switching speeds and current carrying capacity can be achieved due to its highest carrier mobility for both electrons and holes of the three materials. Its large bandgap also translates to a high critical breakdown field in diamond, which allows for devices to be manufactured with greater hold off voltage or with smaller footprints. This translates directly into several performance advantages, as well as reduced system cost. More uniquely, its high thermal conductivity will allow for better thermal management and reduced cooling system requirements, which can further contribute to reduced system footprint, complexity, and cost. Past studies have shown photoconductivity in intrinsic diamond by UV-band excimers in high electric fields up to 2 MV/cm. For many applications, however, the high energy excitation source required may be limiting and there is ample room for improvement.

In accordance with certain of the above-discussed experimental embodiments, FIG. 4C illustrates the energy band diagram of diamond, including its bandgap (5.65 eV) and the activation energy of its dopants, boron, phosphorous, and nitrogen. Boron as a p-type dopant has an activation energy of 0.3-0.37 eV above the valence band. Phosphorous and nitrogen are n-type diamond dopants, with phosphorous serving as an example of a relatively shallow donor with 0.5-0.65 eV below the conduction band, and nitrogen serving as an example of a relatively deep donor with an activation energy of 1.7 eV.

FIG. 4D illustrates certain material properties of diamond (in comparison to Si at plot 465 and other wide band gap materials GaN and SiC at plots 470 and 475) in accordance with certain example aspects of the present disclosure, which aspects are preserved in the ensuing doped material obtained by the diamond-based growth methodology disclosed herein. More specifically and according to the present disclosure for use in a diamond-based photoconductive switch, such methodology includes forming the doped diamond-grown material by combining different gases on a diamond seed to manifest a controlled dopant concentration level of a polarity type and over a depth of optical sufficient absorption (e.g., to ionize the dopants) in response to an optical signal, and diamond has been found to be an ideal material for high power and high temperature electronics assuming that such methodology preserves (in the resultant material) certain diamond properties of interest including, as examples, one or more of the following properties as depicted by the outer (thick) line 460: large bandgap energy (5.65 eV), high breakdown electric field (˜10 MV/cm), high carrier (bulk) mobility (˜2200 and ˜1600 cm2/Vs for electrons and holes, respectively), high thermal conductivity (˜10⁻²⁰ W/cm·K), and excellent resistance to radiation.

Also according to the present disclosure, more-detailed/experimental embodiments are useful for showing and validating the above and further exemplary aspects in connection with apparatuses and methods disclosed herein. In such more-specific experimental examples according to the present disclosure, certain embodiments are directed to methodology and related experimental system approaches involving two diamond substrates: one with a 1 μm doped boron epilayer grown by MPCVD on a diamond High Pressure High Temperature (HPHT) synthesized seed and one entirely nitrogen doped HPHT diamond sample. The boron doped sample devices (“samples”) had two ohmic contacts of Ti/Pt/Au˜100 μm wide separated by 20 μm on the same plane. The nitrogen sample had interdigitated ohmic contacts of Ti/Pt/Au spaced 20 μm apart deposited by electron-beam evaporation.

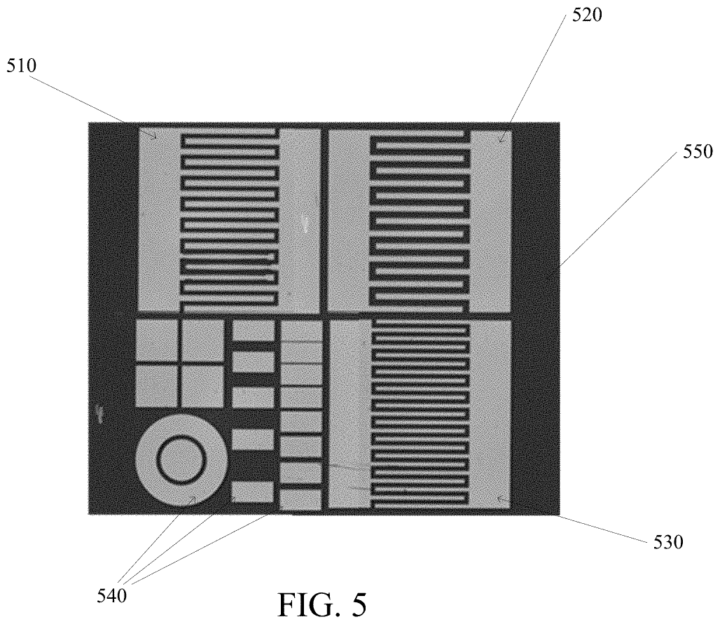

In connection with the experimental embodiment associated with the nitrogen sample, FIG. 5 illustrates an example set of fabricated planar interdigitated photoconductive switches 510, 520 and 530 in three quadrants on an upper surface of a nitrogen-doped diamond material 550. In the fourth quadrant, example electrical test structures 540 are depicted. Each of the photoconductive switches 510, 520 and 530 may be manufactured, used and/or tested for operation as discussed above in connection with planar-contacts type photoconductor of FIG. 4A.

Further in connection with FIGS. 4A and 4B, it can be observed that at least three general layouts of a device (e.g., PCSS) may be realized, depending on the contact orientation and/or use of a N-doped or P-doped epilayer or (epilayer co-doped with N- and P-type dopants as in each instance the dopants may be N-type and/or P-type). FIG. 4A is associated with first and second planar (e.g., metal transparent or semitransparent) contact layouts, and FIG. 4B is associated with a vertical contact layout. For first of these three, a planar device has a doped epilayer over an intrinsic bulk substrate (not shown) and surface illumination of the epi layer causes dopants in the epilayer to ionize and conduct current near the surface from the positive contact towards the negative contact. The second planar device has the entire substrate (area below the contacts of FIG. 4A) doped, and surface illumination causes dopants in the upper portion or entire substrate to be ionized based on the absorption depth. For the third, the vertically-oriented device (as in FIG. 4B) has the entire substrate is doped, and illumination from the side of the substrate causes ionization of the dopants so as to induce a photocurrent that flows vertically through the bulk substrate. In connection with the vertical orientation of FIG. 4B, it can be recognized that if the contacts are semi-transparent, surface illumination can also be utilized.

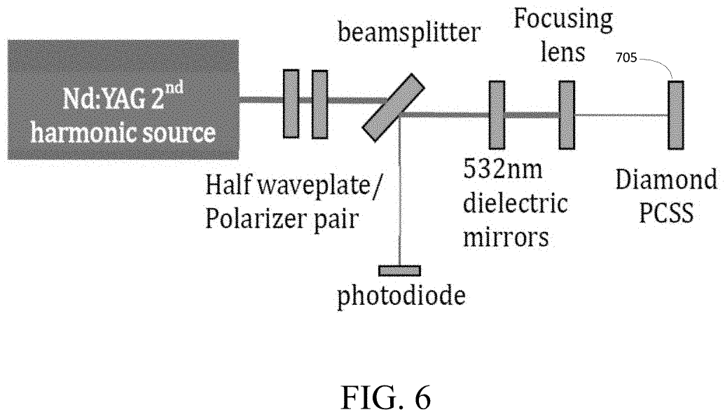

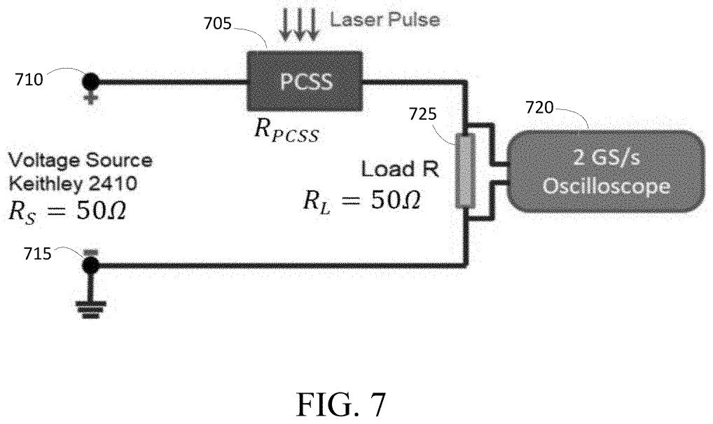

As shown in FIG. 6 and in FIG. 7, testing of the extrinsic diamond substrate 705 (shown in both FIGS. 6 and 7) of such sample or samples may be performed by exciting with a frequency doubled (532 nm) Nd:YAG pulsed laser with an output energy of <1 mJ and ˜10 ns duration. The measurement circuit includes a DC voltage supply (applied via contacts 710 and 715 of FIG. 7) in series with the diamond-based PCSS substrate 705 and load resistor (725 of FIG. 7) whose voltage may be measured by an oscilloscope and resistor. When the PCSS is illuminated in the on-state, the voltage across the load increases in response since the PCSS and load resistor act as a voltage divider.

FIG. 7 illustrates such measurement circuit used to record the photoresponse of the photoconductive switch, in the form of a PCSS 705 constructed according to the present disclosure, and in conjunction with the example optical setup in FIG. 6. By applying a voltage across the positive and negative (or common) contacts 710 and 715 and a laser pulse at the diamond-based PCSS 705, an oscilloscope 720 (or other impedance meter) may be used to measure and confirm the decreased resistance across the load R depicted as 725.

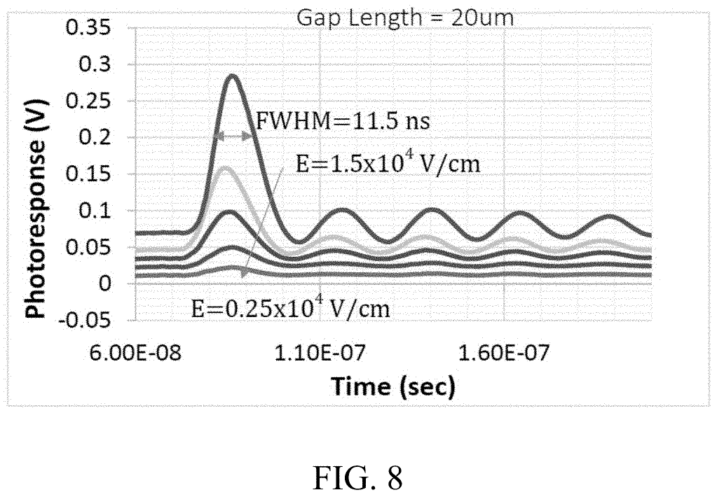

Certain experiments with the above-noted apparatuses/devices show a pulsed photoresponse in both devices. In connection with the boron-doped sample and using the example measurement circuit of FIG. 7, FIG. 8 illustrates an example photoresponse of the sample with two contacts to a 532 nm laser pulse measured. As depicted, the measurement circuit of FIG. 7 records a pulse with a full-width half maximum (FWHM) of 11.5 ns.

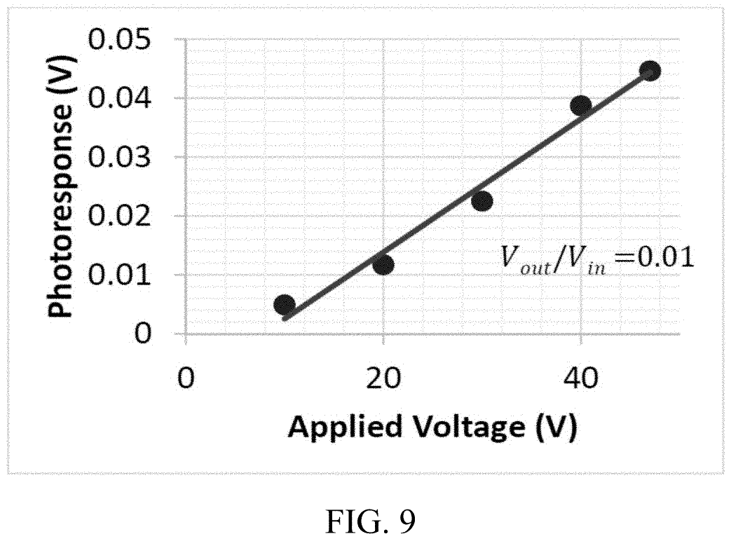

In certain of the experimental tests and as depicted in connection with FIG. 9, the device may be biased such that the electric field across the electrodes is ranging from 0.25-1.5×10⁴ V/cm linear relationship and being established between the photoresponse peak and the bias voltage, and sharper rise times and slower fall times may be observed, which may be due to the presence of traps or thermal effects. Aided by residual heating from the source, its captured carriers may remain thermally excited leading to a current tail.

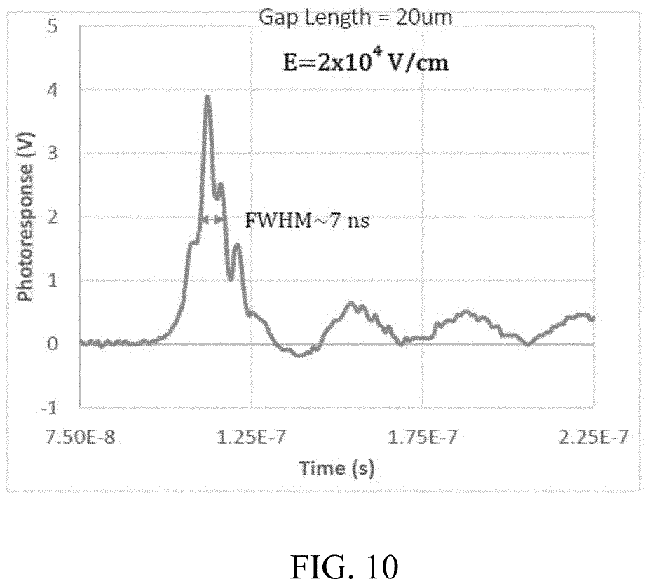

In connection with the nitrogen-doped sample (such as one of the previously-discussed nitrogen-doped diamond photoconductive switch examples) and as depicted in connection with the graph of FIG. 10, the photoresponse to a 532 nm pulsed laser may show a much sharper peak (FWHM of 7 ns), and a magnitude higher in voltage with an electric field of 2.0×10⁴ V/cm. Additionally, the dark current was exceptionally small, ˜0.5 nA. In such an example, the calculated dark resistance and “on” resistance is ˜80 GΩ and 450Ω, respectively, translating to a large on/off current ratio on the order of 10⁸. In other examples, each such associated dark resistance and “on” resistance translates to a large on/off current ratio from most anywhere above and below this calculated degree depending, for example, on the control and selection of dopant(s), etc.

Through this experimental work in accordance with aspects of the present disclosure, photoconductivity was successfully shown in extrinsic homoepitaxial diamond using a lower energy, below bandgap Vis-NIR excitation source. Also in accordance with aspects of the present disclosure, further experimental work confirms the performance and dopant-material type variations applicable herein. Such further experimental embodiments and aspects, along with performance attributes, are presented below.

In connection with such experimental work, extrinsic diamond PCSSs were fabricated in an interdigitated planar configuration (as illustrated and discussed previously), with a comparison of the effects of different doping methods such as boron doped CVD growth, HPHT grown nitrogen doped diamond, and boron-implanted diamond. As illustrated with Tables I and II below, five PCSS devices (Table I were fabricated on various types diamond substrates.

TABLE 1
(Diamond Classification)

| | | |
|---|---|---|
| Type I | Type Ia | Aggregate N |
| N impurities | Type Ib | Single N |
| Type II | Type IIa | Undoped |
| No N impurities | Type IIb | Single B |

The boron implantation was performed on devices Ib-B and IIa-B with a total dose of 4.5×10¹⁴ cm², and simulated on SRIM to produce a Boron profile with a peak of 3×10¹⁹ cm⁻³ and depth of 200 nm. A 100 nm SiO2 cap was then deposited by e-beam evaporation to prevent surface graphitization during the dopant activation process which involved annealing the implanted diamond samples for 2 hours at 1100° C. with a background Ar flow of 2 splm at 10⁻³ torr. Secondary Ion Mass Spectrometry (SIMS) measurements were performed on these samples afterwards by Advanced Materials Analysis Inc. yielding the actual implantation and background doping profile. The peak boron concentration was 3.2×10¹⁹ cm⁻³ in both implanted samples within 40 nm below the surface. Ib samples were measured to have a nitrogen concentration of 1.32×10¹⁹ cm⁻³, while IIa samples 1×10¹⁶ cm³.

TABLE II
(Diamond Samples Used in Experimental Studies)

| | | |
|---|---|---|
| Device | Substrate | Additional Doping |
| Ib | HPHT Ib | Boron implantation |
| Ib-B | HPHT Ib | |
| IIa-B | CVD IIa | Boron implantation |

Three PCSS devices (Table II) were fabricated on various types diamond substrates, which are described in Table 1. The two nitrogen doped Ib diamond samples were grown by high pressure high temperature (HPHT), and one underwent boron implantation (Ib-B). The two undoped IIa diamond samples were grown by CVD, with one that underwent boron implantation (IIa-B). Finally, the last sample has a 1 mm boron doped epilayer grown on a IIa diamond CVD grown seed (B-epi).

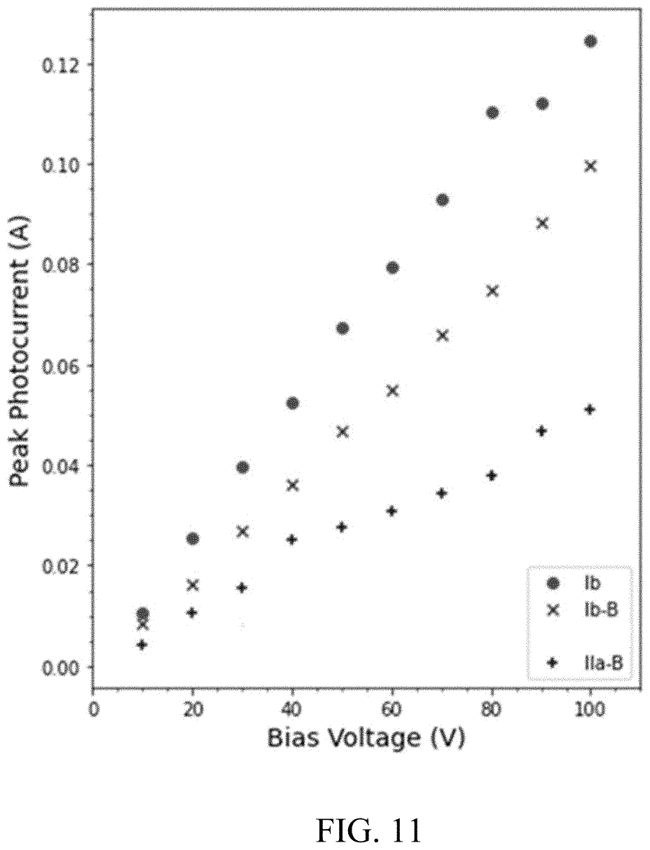

When excited by a 532 nm source, a photoresponse was observed in all devices. A summary of switch performance with a 532 nm excitation source is summarized in Table III showing the highest Roff/Ron ratio from device Ib and with devices on nitrogen doped Ib substrates generally showing better switching performance. The peak photocurrent of the PCSS devices followed a linear relationship with respect to the bias voltage up to 100 V and a laser pulse energy of 0.8 mJ as shown in FIG. 11. This linear behavior is consistent with other wide bandgap materials such as SiC and GaN.

TABLE III
(Switch Performance with 532 nm Source)

| Device | R_{off} (Ω)^{a} | Rₒₙ (Ω)^{a} | R_{off}/Rₒₙ^{a} |
|---|---|---|---|
| Ib | 4.3 × 10¹⁴ | 753 | 5.71 × 10¹¹ |
| Ib-B | 1.5 × 10¹⁴ | 960 | 1.56 × 10¹¹ |
| IIa-B | 1.9 × 10¹² | 1911 | 9.94 × 10⁸ |

Note:
^{a}= At a charge bias of 100 V and 0.8 mJ 532 nm laser pulse

FIG. 11 is a graph showing plots of peak photocurrent of nitrogen-doped and implanted-boron devices up to 100V bias voltage (0.33-3.33×10⁴ V/cm) in response to a 532 nm excitation source with 0.8 mJ energy. Accordingly, it is observed that as the energy of the laser is 4 increased, the generated photocurrent increases, and the minimum resistance of the PCSS decreases. This can be explained by the equations for photo-conductivity, as a function of the number of carriers generated from photoexcitation (nₚₕₒₜₒ), where the photo-conductivity is equal to 1/qμₙnₚₕₒₜₒ, and nₚₕₒₜₒ is equal to ηEexc (λ/hc) (1−R)(1−exp(−αd)), and where and η is the quantum efficiency, Eexc is the portion of energy from the excitation laser that is seen by the exposed device area, λ is the wavelength of light, R is the reflectivity, a is the absorption coefficient, and d is the thickness of the diamond.

In a linear PCSS, the on conductance should thus increase linearly with laser power. In Ib diamond based devices, the linear behavior is captured up to about 1.5 mJ after which saturation effects are observed. This behavior is more prominent in the more-conductive devices and not observed in IIa diamond based devices. When the same study is conducted with 1064 nm light, photoresponses are only observed in devices IIa-B. Since 1064 nm (1.165 eV) light does not provide sufficient energy to ionize substitutional nitrogen, no photoresponse is observed in device Ib or IIa. On the other hand, since boron's activation energy is 0.37 eV, 1064 nm photons have sufficient energy to ionize substitutional boron, a photoresponse is observed on device IIa-B and B-epi.

For the device (or sample) that underwent boron implantation (IIa-B), peak photocurrent (A) at different bias voltages (V) measure respectively at about: 0.0018 (A) for 50 (V); 0.0024 (A) for 70 (V); 0.0034 (A) for 100 (V); and 0.0042 (A) for 133 (V).

In view of the above discussion, it may be appreciated that the Specification describes and/or illustrates aspects useful for implementing the claimed disclosure by way of various circuits or circuitry which may be illustrated as or using terms such as material layers, blocks, modules, device, system, controller, and/or other circuit-related depictions. Such circuit- or circuitry-directed illustrations may be used together with other elements to exemplify how certain example embodiments may be carried out in the form or structures, steps, functions, operations, activities, etc.

In connection with certain further specific embodiments of the present disclosure, n-doped diamond is used to develop and to operate an optically-controlled gate for a high-voltage diamond switching device such as a transistor. In connection with such specific embodiments using n-doped diamond, detailed experimental embodiments have shown that such devices work well with optical triggering. In more specific example embodiments of the present disclosure, n-doped diamond is integrated with other semiconductors (e.g., semiconductive material layers) to form conductive paths that are only active with light of specific wavelengths or specific-wavelength ranges (including but not limited to ranges specific to or including 1.55 microns and others).

Advantageously, n-doped diamond offers high (e.g., perhaps the highest known) On:Off ratio in devices such as a PCSS since (e.g., n-type) doping can be used to form a contact layer as well as a channel in the diamond device, only when triggered with the optical pulse. Under dark condition or environment there is hardly any (e.g., negligible) leakage current flowing, thereby yielding optimal efficiencies. Again, while PCSS is one type of device that might be benefited by such aspects of the present disclosure, the present disclosure is not so limited as such structures and methodology also apply to other devices including, as examples, light-controlled transistors, thyristors, etc. Accordingly, for example devices discussed in connection with FIGS. 4A and 4B, the (planar-oriented and/or vertically-oriented) contacts can be formed by doping so that the channel in the diamond device conducts through the contacts only when triggered with the optical pulse (and in certain instances, permitting an offset of specifications associated with formation of the channel).

The skilled artisan would also recognize various terminology as used in the present disclosure by way of their plain meaning. As examples, the Specification may describe and/or illustrates aspects useful for implementing the examples by way of various semiconductor materials/circuits which may be illustrated as or using terms such as layers, blocks, modules, device, system, unit, controller, and/or other circuit-type depictions. Also, in connection with such descriptions, the term “source” may refer to source and/or drain interchangeably in the case of a transistor structure. Such semiconductor and/or semiconductive materials (including portions of semiconductor structure) and circuit elements and/or related circuitry may be used together with other elements to exemplify how certain examples may be carried out in the form or structures, steps, functions, operations, activities, etc. It would also be appreciated that terms to exemplify orientation, such as upper/lower, left/right, top/bottom and above/below, may be used herein to refer to relative positions of elements as shown in the figures. It should be understood that the terminology is used for notational convenience only and that in actual use the disclosed structures may be oriented different from the orientation shown in the figures. Thus, the terms should not be construed in a limiting manner.

Based upon the above discussion and illustrations, those skilled in the art will readily recognize that various modifications and changes may be made to the various embodiments without strictly following the exemplary embodiments and applications illustrated and described herein. For example, methods as exemplified in the Figures may involve steps carried out in various orders, with one or more aspects of the embodiments herein retained, or may involve fewer or more steps. Such modifications do not depart from the true spirit and scope of various aspects of the disclosure, including aspects set forth in the claims.

What is claimed:

1. An apparatus comprising:
a diamond-based photoconductive switch; and
a doped diamond-grown material in the diamond-based photoconductive switch, the doped diamond-grown material being formed from different gases combined on a diamond seed and therefrom manifest a controlled dopant concentration level with dopants of a polarity type and over a depth of optical absorption sufficient to ionize the dopants in response to an optical signal.

2. The apparatus of claim 1, further including: a plurality of contacts, each being respectively coupled to the diamond-based photoconductive switch; and an excimer source to generate the optical signal at energies greater than an activation energy and less than the bandgap of the doped diamond-grown material, wherein the diamond-based photoconductive switch is to respond to the generated energies by generating electric current via at least one of the plurality of contacts.

3. The apparatus of claim 1, wherein the optical absorption is to occur in response to an excimer source, in conjunction with free carriers generated in the doped diamond-grown material to be sourced primarily from atoms of one or more dopants of the doped diamond-grown material.

4. The apparatus of claim 1, wherein the diamond-based photoconductive switch includes a p-n junction that is to convert photons into current and that manifests a breakdown voltage of at least 1 kV with a blocking electric field of at least 2 MV/cm.

5. The apparatus of claim 1, wherein the controlled dopant concentration level is greater than 10¹⁹ cm⁻³ based on one or more n-type dopants.

6. The apparatus of claim 1, wherein the polarity type is n-type, and the controlled dopant concentration level is between than 10¹⁹ cm⁻³ and 10²⁰ cm⁻³′ and the depth of optical absorption is at least 103 nm.

7. The apparatus of claim 1, wherein the polarity type is p-type and the controlled dopant concentration level is based on one or more dopants including Boron.

8. The apparatus of claim 1, wherein the polarity type is p-type, the controlled dopant concentration level is based on one or more of dopants, and the depth of optical absorption is at least 500 nm.

9. The apparatus of claim 1, wherein the diamond-based photoconductive switch includes or refers to a photoconductive semiconductor switch.

10. The apparatus of claim 1, wherein the diamond-based photoconductive switch refers to or is part of one or more of the following: a Gate Turn Off Thyristor (GTO), a Silicon Controlled Rectifier (SCR), and high-voltage field-effect transistor (FET).

11. The apparatus of claim 1, further including a plurality of contacts being arranged along a layer which is coupled to a surface of a substrate material which includes the doped diamond-grown material with the dopants located in the substrate material proximal to the surface.

12. The apparatus of claim 11, wherein the substrate material includes an epi layer and the dopants are located in an epi layer of the substrate material.

13. The apparatus of claim 1, further including a plurality of contacts being arranged vertically on each of a first side and a second side of a substrate material that includes the doped diamond-grown material, and wherein the substrate material is doped across a portion from the first side to the second side.

14. The apparatus of claim 13, wherein the substrate material responds to the optical signal as illuminating the substrate along a direction, from another side of the substrate material, that is parallel to a plane characterizing an interface at which the first side or the second side is coupled to the substrate.

15. The apparatus of claim 13, wherein the substrate material responds to the optical signal as illuminating the substrate along a direction that is orthogonal to a plane characterizing an interface at which the first side or the second side is coupled to the substrate.

16. The apparatus of claim 1, further including a plurality of contacts being coupled to at least one surface of a substrate material, the at least one surface being common to a side of the substrate material, wherein at least one of the plurality of contacts includes the doped diamond-grown material, and wherein in response to the optical signal resistance in said at least one of the plurality of contacts is reduced and current is to be passed between the plurality of contacts to effect an on-state of the diamond-based photoconductive switch.

17. A method comprising:
in a diamond-based photoconductive switch, using a doped diamond-grown material formed from different gases combined on a diamond seed to manifest a controlled dopant concentration level of dopants of a polarity type and over a depth of optical absorption sufficient to ionize the dopants in response to an optical signal, and
generating, via the diamond-based photoconductive switch manifesting ionization of the dopants, electric current.

18. The method of claim 17, wherein one of the different gases is a source of phosphorus.

19. The method of claim 17, wherein one of the different gases is a source of boron.

20. The method of claim 17, wherein one of the different gases is a source of nitrogen.

21. A method comprising:
in a diamond-based photoconductive switch, forming a doped diamond-grown material by combining different gases on a diamond seed to manifest a controlled dopant concentration level of dopants of a polarity type and over a depth of optical absorption sufficient to ionize the dopants in response to an optical signal.

22. The method of claim 21, further including using hydrogen plasma as one of the different gases during growth from the diamond seed, and using methane (CH4) as another of the different gases as a source of carbon.

23. The method of claim 21, wherein one or more dopants of the doped diamond-grown material includes phosphorus, and the method further includes using trimethyl phosphine (TMP) diluted with hydrogen (P(CH3)3) as a source of the phosphorus.

24. The method of claim 21, wherein combining different gases includes using a vapor-input or vapor-deposition tool to combine the different gases and/or to control the dopant concentration level; and the method further includes:
removing hydrogen conduction from a surface of the diamond-grown material;
measuring or characterizing a depth profile of one or more dopants of the polarity type in the doped diamond-grown material; and
measuring or characterizing a level of activation energy of the one or more dopants in the diamond-grown layer.

25. The method of claim 21, further including using an excimer source to cause the optical absorption and to excite carriers in the doped diamond-grown material by sub-bandgap photon energies, wherein the step of forming includes generating the doped diamond-grown material with thermal-management properties and voltage-breakdown properties of diamond.

26. The method of claim 21, wherein the optical absorption is to occur in response to the optical signal an excimer source, in conjunction with free carriers generated in the doped diamond-grown material to be sourced primarily from atoms of one or more dopants of the doped diamond-grown material, and wherein the diamond-based photoconductive switch includes a p-n junction that is to convert photons into current and that manifests a breakdown voltage of at least 2 kV with a blocking electric field of at least 2 MV/cm.

27. The method of claim 21, wherein the diamond-based photoconductive switch includes a p-n junction that is to convert photons into current and that manifests a breakdown voltage of at least 2 kV.

28. The method of claim 21, wherein the diamond-based photoconductive switch includes a plurality of contacts being arranged along a layer which is coupled to a surface of a substrate material which includes the doped diamond-grown material with the dopants located in the substrate material proximal to the surface.

29. The method of claim 28, wherein the substrate material includes an epi layer and the dopants are located in an epi layer of the substrate material.

30. The method of claim 21, wherein the diamond-based photoconductive switch includes a plurality of contacts being arranged vertically on each of a first side and a second side of a substrate material that includes the doped diamond-grown material, and wherein the substrate material is doped across a portion from the first side to the second side.

31. The method of claim 30, wherein the substrate material responds to the optical signal as illuminating the substrate along a direction, from another side of the substrate material, that is parallel to a plane characterizing an interface at which the first side or the second side is coupled to the substrate.

32. The method of claim 30, wherein the substrate material responds to the optical signal as illuminating the substrate along a direction that is orthogonal to a plane characterizing an interface at which the first side or the second side is coupled to the substrate.

33. The method of claim 21, wherein the diamond-based photoconductive switch includes a plurality of contacts being coupled to at least one surface of a substrate material, the at least one surface being common to a side of the substrate material, wherein at least one of the plurality of contacts includes the doped diamond-grown material, and wherein in response to the optical signal resistance in said at least one of the plurality of contacts is reduced and current is passed between the plurality of contacts to effect an on-state of the diamond-based photoconductive switch.
